(19) United States
(12) Patent Application Publication
(10) Pub. No.: US 2026/0092393 A1
(43) Pub. Date: Apr. 2, 2026

(54) CRYSTAL PULLING FROM A HIGHLY IMPURE GROWTH MELT

(71) Applicant: Blue Origin, LLC, Kent, WA (US)

(72) Inventors: Alexander Imbault, Sierra Madre, CA (US); Alex M. Román, Santa Monica, CA (US); Jonathan Grandidier, IV, Pasadena, CA (US); Jeong Chul Lee, Monrovia, CA (US); Jean Chuong, Los Angeles, CA (US); Eric D. Contreras, San Dimas, CA (US); Andrew P. Lange, Thousand Oaks, CA (US)

(21) Appl. No.: 18/904,913

(22) Filed: Oct. 2, 2024

(51) Int. Cl. C30B 15/20; C25C 3/34; C25C 7/00; C30B 29/06

(52) U.S. Cl. CPC C30B 15/20; C25C 3/34; C25C 7/005; C30B 29/06

(57) ABSTRACT

A method and system for crystal pulling from a growth melt that is produced by molten oxide electrolysis are presented. The method may be used as a purification step in processing raw feedstock such as lunar regolith. The Czochralski technique is a similar, but substantially different, process of crystal pulling from a growth melt. In the Czochralski technique, the growth melt is a very pure liquid of the element that is to be formed into a single crystal. In embodiments described herein, the growth melt is substantially impure and may be a combination of two or more elements having similar concentrations, even though only one of the elements is to be formed into a single crystal.

### BACKGROUND

Raw materials, such as that on Earth or the Moon, may generally lead to materials with impurities that are undesired in subsequent steps of production or fabrication. For example, lunar regolith contains minerals primarily comprising elements such as silicon, titanium, aluminum, magnesium, iron, and calcium, which are typically measured and expressed in their oxide form.

Molten oxide electrolysis (MOE) is being pursued as an alternative for existing terrestrial metal production technologies as well as for in situ oxygen and metal production on planetary bodies such as the Moon. MOE is a process that may be used to reduce molten oxides to their metal or metalloid form using an electric current. Accordingly, MOE may be used as an electrometallurgical technique for production of metal or metalloids in the liquid state from oxide feedstock.

In the Czochralski Method, which is also called crystal pulling, a single crystal is grown from a growth melt by slowly pulling a seed crystal out of the growth melt while rotating it. The Czochralski Method is widely used for producing high-quality semiconductor crystals and other single crystals for various applications, for example. Generally, the growth melt in the Czochralski Method is highly pure because the purity of the melt significantly impacts the quality of the resulting single crystal. For example, impurities in the melt can introduce defects into the crystal lattice during growth.

### BRIEF DESCRIPTION OF THE DRAWINGS

The disclosure will be understood more fully from the detailed description given below and from the accompanying figures of embodiments of the disclosure. The figures are used to provide knowledge and understanding of embodiments of the disclosure and do not limit the scope of the disclosure to these specific embodiments. Furthermore, the figures are not necessarily drawn to scale.

FIG. 1 is a schematic cross-section of a molten oxide electrolysis system, according to some embodiments.

FIG. 2 is an example melt profile that represents the melt temperature of a silicon-tin mix as a function of their respective concentrations.

FIG. 3 is an example melt profile that represents the melt temperature of a silicon-magnesium mix as a function of their respective concentrations.

FIG. 4 is a flow diagram of a process for crystal pulling from a growth melt that is produced by molten oxide electrolysis, according to some embodiments.

### DETAILED DESCRIPTION

This disclosure describes, among other things, a system and a method for crystal pulling from a growth melt that is produced by molten oxide electrolysis. For example, the method may be used as a purification step in processing raw feedstock such as lunar regolith. The general Czochralski technique is a similar, but substantially different, process of crystal pulling from a growth melt. In the general Czochralski technique, the growth melt is a very pure liquid of the element that is to be formed into a single crystal. In embodiments described herein, however, the growth melt is substantially impure and may be a combination of two or more elements having similar concentrations (or substantially high concentrations), even though only one of the elements is to be formed into a single crystal. For example, a growth melt for crystal pulling silicon may be 50% silicon and 50% tin. Here, the tin may be considered the impurity and is left in the growth melt as the silicon is pulled from the melt into the forming silicon crystal. This is in contrast to a silicon growth melt for the general Czochralski technique that may have no more than a few parts per million of impurities.

Molten oxide electrolysis (MOE) may be used to separate out constituent materials from a metal oxide feedstock, such as lunar or Martian regolith. If MOE is used in this way to purify any particular constituent element, for example, then a subsequent crystal pulling, as described herein, may be a step for achieving further purification.

A metal oxide in a vessel may be reduced, using MOE, into a relatively heavy liquid metal that sinks toward the bottom of the vessel. At least a portion of this liquid metal may form a liquid metal cathode. In contrast to a heavy liquid metal, some metals reduced by MOE are neutrally buoyant in, or less dense than, their associated molten oxide electrolytes and therefore float in the molten metal oxide.

In embodiments, a method may involve a first vessel and a second vessel. The first vessel includes a molten mixture of a metal oxide and a heavier liquid metal cathode, which may but need not have been formed via electrolysis. As just mentioned, due to its relative density, the heavier liquid metal cathode may sink to the bottom of the first vessel. A portion of the resulting electrolyte may become iron- and oxygen-depleted and may subsequently be extracted from the first vessel and transported into the second vessel. The iron- and oxygen-depleted electrolyte in the second vessel may then be used as a growth melt for crystal pulling. As explained below, at least during the crystal pulling process, the temperature of the growth melt (e.g., the iron- and oxygen-depleted electrolyte) in the second vessel may be carefully controlled to maintain the growth melt within a relatively small margin of its melt temperature. Importantly, this melt temperature generally changes as the concentration of the element being pulled changes in the growth melt.

In some embodiments, an MOE system may comprise a first vessel that includes an anode and a cathodic electrode, which may be located at or near the bottom of the first vessel. The anode and cathodic electrode may be part of a single electrical circuit that includes a voltage or current source. Accordingly, a current may flow between the anode and cathodic electrode, creating a voltage difference across molten oxide material that is between the anode and cathodic electrode. Per its location in the first vessel, the cathodic electrode is configured to be in electrical contact with contents at or near the bottom of the first vessel. The electrical current between the anode and cathodic electrode may allow for a process of electrolysis of the oxide material. The electrolysis of the oxide material may lead to formation of an electrolyte and either the formation of a cathode material or the creation of metal that can dissolve into an already existing liquid cathode, which is in electrical contact with the cathodic electrode.

The MOE system may further comprise a second vessel that is separated from the first vessel by a conduit that carries a portion of the electrolyte from the first vessel to the second vessel. In some implementations, the MOE system need not include such a conduit and portions of the electrolyte may be transported from the first vessel to the second vessel by any of a number of ways. Because of the electrolysis process forming the cathode material and the oxidation process, the portion of the electrolyte carried by the conduit (or by other methods) may be depleted of iron and oxygen. As mentioned above, the portion of the electrolyte provided into the second vessel by the conduit may include an element, among other elements or compounds, that is targeted for crystal pulling.

In some implementations, the MOE system may further comprise a temperature controller to control the temperature of the portion of the electrolyte that is in the second vessel and/or the conduit. In some implementations, the MOE system may further comprise a seed holder in or above the second vessel for crystal pulling. For example, the seed holder may receive instructions from a system controller to raise or lower based on a temperature that is measured by temperature sensors that provide thermal data about the second vessel to the system controller. For example, Laser Induced Breakdown Spectroscopy (LIBS) may be used to measure temperatures of molten materials. Other techniques may be used for measuring temperatures and claimed subject matter is not limited in this respect. The system controller may also, or instead, enable the MOE system, which may comprise a combination of electrical and mechanical components, to collect the crystal formed by the crystal pulling in the second vessel while simultaneously performing the electrolysis in the first vessel.

In some implementations, the temperature-control electronics may be configured to decrease the temperature of the portion of the melted oxide material as the concentration of the silicon decreases. Conversely, the temperature-control electronics may also be configured to increase the temperature of the portion of the melted oxide material as the concentration of the silicon decreases.

In some implementations, oxide material used in the method may be derived from lunar regolith. For example, iron oxide may be in lunar regolith, or in minerals found on off-Earth locations and/or objects in the Solar System, such as asteroids, moons, minor-planets, and planets, among other objects. Of course, iron oxide is also present on Earth, and methods described herein may be performed on Earth, the moon, or other bodies listed above, and claimed subject matter is not limited in this respect.

As indicated above, embodiments herein are directed to crystal pulling that involves controlling (by any of a number of techniques) the temperature of a growth melt. This temperature control allows for crystal pulling of a single element, for example, from a growth melt that is a combination of two or more elements or compounds. An example that is illustrated herein is crystal pulling from a growth melt of silicon and tin to form a crystal (e.g., an ingot) of silicon, wherein the tin is left behind in the growth melt. Thus, the concentration of tin in the growth melt increases. Claimed subject matter is not limited to any particular growth melt composition.

Crystal pulling as described herein is similar to the Czochralski Method, wherein a single crystal is grown from a growth melt by slowly pulling a seed crystal out of the growth melt while rotating the seed crystal. In contrast to embodiments of crystal pulling described herein, however, growth melt in the typical Czochralski Method is highly pure because the purity of the growth melt significantly impacts the quality of the resulting single crystal. This is generally important when the Czochralski Method is used for producing high-quality semiconductor crystals and other single crystals. For example, impurities in the growth melt can introduce defects into the crystal lattice during crystal growth. High-purity growth melts generally lead to fewer lattice imperfections, resulting in a higher-quality crystal. In semiconductor crystal growth, specific dopants (impurities intentionally added) determine the crystal's electrical properties. Precise control over dopant concentration requires a pure growth melt, which also ensures uniform distribution of dopants throughout the crystal. In contrast, non-uniform dopant distribution generally affects device performance. Contaminants (unintended impurities) can alter crystal properties. High-purity growth melts minimize contamination. Accordingly, maintaining a highly pure growth melt is generally important for achieving desired crystal properties and minimizing defects.

In embodiments herein, however, producing high-quality single crystals, such as those that may be used in semiconductor electronics, is not necessarily a priority. Instead, embodiments of crystal pulling described herein may be applied to forming crystals that may have a substantial amount of impurities but can nevertheless be used for solar panels or other applications where high quality crystals are not a priority. Though the crystals formed by the crystal pulling embodiments described herein may include such impurities, the crystal pulling may still result in a substantial increase in purity from the growth melt to the formed crystal. And in some implementations, the resulting crystal may be of high-quality and relatively pure in reference to semiconductor standards. Claimed subject matter is not limited in this respect.

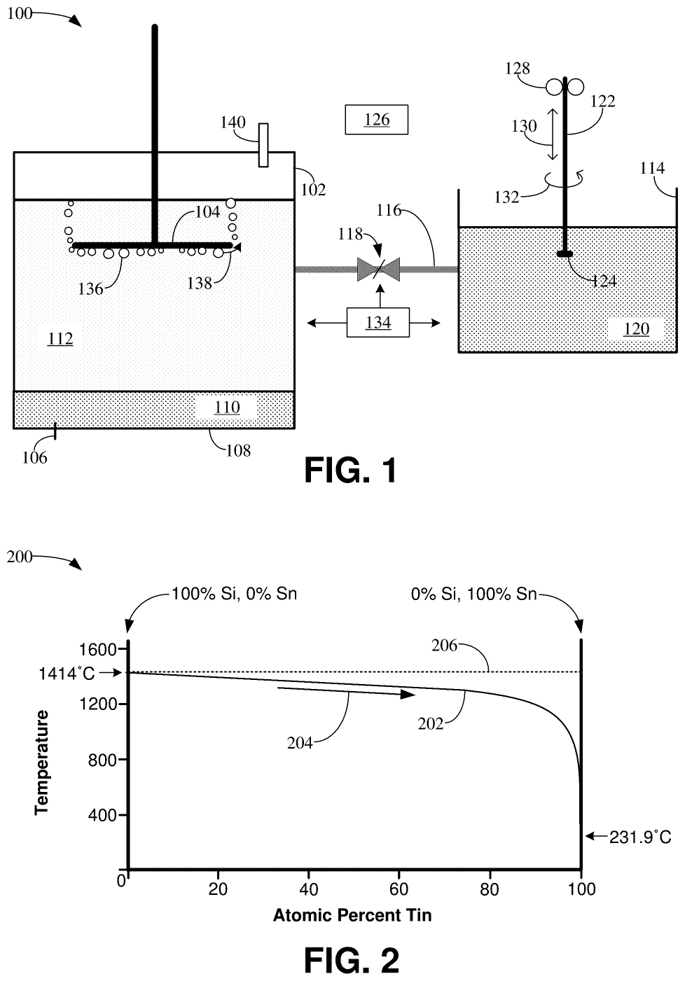

FIG. 1 is a schematic cross-section of an MOE system 100, according to some embodiments. Various portions of the system, as illustrated, are not necessarily to scale. The MOE system generally comprises electrical and mechanical components that are interfaced with one another in various configurations. The MOE system may further comprise one or more computer processors configured to execute computer-readable instructions, which may be directed to controlling at least some of the electrical and mechanical components.

MOE system 100 may include a first vessel 102 (e.g., an electrolysis vessel), an anode 104 protruding into the first vessel from above, and a cathodic electrode 106, which may be located at or near the bottom 108 of the first vessel. The cathodic electrode is configured to be in electrical contact with a lower portion of contents, such as a liquid cathode 110, contained in first vessel 102. The anode and cathodic electrode may be part of a single electrolysis circuit that includes a voltage or current source (not illustrated). Accordingly, a current may flow between the anode and cathodic electrode, creating a voltage difference across molten oxide material 112 that is between the anode and cathodic electrode. For example, in some implementations, a generic composition of oxides may be: SiO2+Al2O3+MgO+FeO+CaO+SnO with trace alkali oxides and halides. The electrical current between the anode and cathodic electrode may allow for a process of electrolysis of oxide material 112. Distances between the anode and cathodic electrode may be varied to adjust voltage and/or current of the electrolysis circuit. Such variation may be useful to account for varying resistivity of molten oxide material 112 and liquid cathode 110, for example. As explained above, the electrolysis of molten oxide material 112 may produce an iron liquid cathode 110 which, in embodiments described herein, is denser than the surrounding molten oxide material. Accordingly, the liquid cathode will sink toward the bottom of first vessel 102 and thus be in electrical contact with cathodic electrode 106. It is this production of the iron liquid cathode that results in iron depletion of a portion of molten oxide material 112 (wherein this iron-depleted portion may be transferred to second vessel 120, as explained below).

MOE system 100 may further comprise a second vessel 114 (e.g., a crystal pulling vessel) that is separated from first vessel 102 by, in some implementations, a conduit 116 that is configured to carry to the second vessel a portion of molten oxide material 112 that has been, by electrolysis, depleted of iron and oxygen. This depletion will be explained in detail below. The conduit, which may contain a flow control valve 118, may be a tube, pipe, channel, or connecting chamber, just to name a few examples.

During operation of MOE system 100, the portion of molten oxide material 112 that has been depleted of iron and oxygen, hereinafter called iron- and oxygen-depleted electrolyte, may flow into second vessel 114, at least partially filling the vessel with the iron- and oxygen-depleted electrolyte 120.

System 100 further includes, above vessel 114, a seed holder 122 that may be configured to raise or lower a seed crystal 124 that is used for crystal pulling. In some implementations, MOE system 100 may include a system controller 126 that provides instructions to a motion transducer 128 to move seed holder 122 to raise or lower seed crystal 124 during the process of crystal pulling. In addition to vertical translational motion 130, motion transducer 128 may also be able to provide rotational motion 132 to seed holder 122.

Crystal pulling in vessel 114 involves a process of forming a single crystal on seed crystal 124 of an element that is in iron- and oxygen-depleted electrolyte 120. Accordingly, in this situation, iron- and oxygen-depleted electrolyte 120 is the growth melt of the crystal pulling. Because crystal pulling relies on the temperature of the growth melt being just above its melt temperature, a temperature controller 134 may be used to control the temperature(s) of iron- and oxygen-depleted electrolyte 120 during seed pulling. In some implementations, temperature controller 134 may also be configured to control temperatures of various portions of system 100, such as molten oxide material 112 and the portion of the iron- and oxygen-depleted electrolyte in conduit 116. The temperature controller may operate in combination with thermal insulation and/or air (or other fluid) circulation systems to at least partially maintain temperature and/or cool the various parts of system 100. For example, conduit 116 may be covered with thermal insulation or other material to prevent the flow of the iron- and oxygen-depleted electrolyte from cooling more than a desired amount. In addition, or instead, conduit 116 may be exposed to a cooling air flow that may be varied by temperature controller 134. In some implementations, locations or distribution of thermal insulation may also be varied by temperature controller 134. First and second vessels may likewise have such insulation or air flow exposure.

In some implementations, system controller 126 may enable MOE system 100 to automatically collect or retrieve the crystal that formed by crystal pulling from seed crystal 124 while simultaneously performing electrolysis in first vessel 102. In this way, the MOE system may allow collection of the crystal without removing or interrupting the electrolysis process in the first vessel. Thus, MOE system 100 may operate continuously instead of operating in batch processes.

Oxygen gas may be produced from the electrolysis process performed in first vessel 102. It is this oxygen gas production that results in oxygen depletion of a portion of molten oxide material 112 (wherein this oxygen-depleted portion may be transferred to second vessel 120, as explained above). In detail, the oxygen gas may generally accumulate on anode 104 as bubbles 136. Due to their buoyancy in the electrolyte, oxygen bubbles 136 may flow to the surface of the electrolyte, as indicated by arrow 138. The oxygen gas from the emerging bubbles may accumulate in a top portion of vessel 102 until the oxygen gas is collected via a port 140, for example.

FIG. 2 is a plot 200 that includes a melt profile 202 that represents the melt temperature of a silicon-tin mix, which may be a growth melt, as a function of their respective concentrations, according to some embodiments. For example, such a mix may be a growth melt for a crystal pulling process, which may be performed in second vessel 114 of MOE system 100. In the left side of plot 200, the growth melt is substantially pure (e.g., 100%) silicon. Here, “substantially” means that there may be a relatively small amount of various impurities that are neither silicon nor tin. For example, such an amount may be small enough to not affect or interfere with the crystal pulling process described herein. In the right side of plot 200, the growth melt is substantially pure (e.g., 100%) tin. The relative concentrations of silicon and tin are indicated on the horizontal axis.

Melt profile 202 illustrates that the melting temperature of this growth melt decreases as the concentration of silicon decreases. For example, when the growth melt is 100% silicon, the melting temperature of the growth melt is the familiar 1414 degrees centigrade for silicon. When the growth melt is 100% tin, the melting temperature of the growth melt is 231.9 degrees centigrade for tin. Starting with 100% silicon, the melting temperature of the growth melt decreases linearly with decreasing concentration of silicon until a concentration of about 30% silicon, 70% tin. Accordingly, the temperature of the growth melt during a pulling process for silicon should follow melt profile 202, as indicated by arrow 204, for example, to promote crystal growth (e.g., growth melt not too hot) and to avoid solidifying the growth melt (e.g., growth melt not too cold). Thus, in this example, and using MOE system 100, temperature controller 134 (e.g., temperature-control electronics) may decrease the temperature of the growth melt as the concentration of the silicon decreases. This is in contrast to crystal pulling from a growth melt that is a 100% concentration of the intended crystal material (e.g., forming a crystal of silicon from pure silicon growth melt (melt temperature of 1414 degrees C.), or forming a crystal of GaAs from pure GaAs growth melt (melt temperature of 1238 degrees C.)). In this case, the temperature of the growth melt is held constant, as indicated by line 206, because the melt temperature of a pure, 100% concentration growth melt does not change, even as material is pulled out to form a crystal. For example, crystal pulling from a growth melt of pure silicon to form a silicon crystal would occur at or very near the melting point of pure silicon, which is 1414 degrees C. In another example, crystal pulling from a growth melt of pure GaAs to form a GaAs crystal would occur at or very near the melting point of pure GaAs, which is 1238 degrees C.

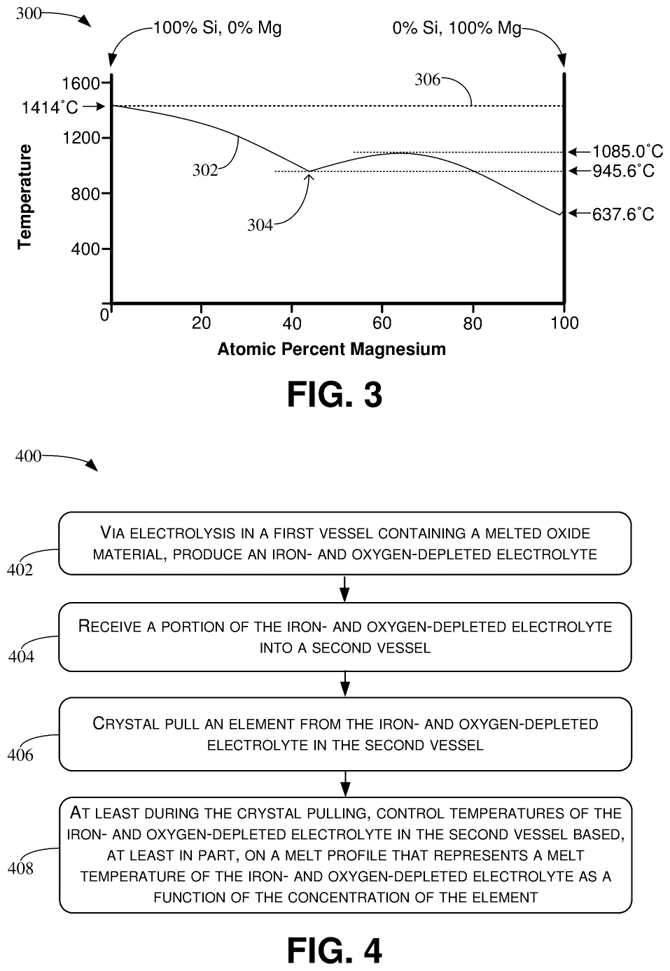

FIG. 3 is a plot 300 that includes a melt profile 302 that represents the melt temperature of a silicon-magnesium mix, which may be a growth melt, as a function of their respective concentrations, according to some embodiments. For example, such a mix may be a growth melt for a crystal pulling process, which may be performed in second vessel 114 of MOE system 100. In the left side of plot 300, the growth melt is substantially pure (e.g., 100%) silicon. Here, “substantially” means that there may be a relatively small amount of various impurities that are neither silicon nor magnesium. For example, such an amount may be small enough to not affect or interfere with the crystal pulling process described herein. In the right side of plot 300, the growth melt is substantially pure (e.g., 100%) magnesium. The relative concentrations of silicon and magnesium are indicated on the horizontal axis. Melt profile 302 may be compared to melt profile 202 because both profiles represent a melt temperature of a growth melt as a function of the concentrations of the constituent elements. Melt profile 302, however, demonstrates a relationship between silicon concentration and growth melt temperature that is more complex (e.g., nonlinear) compared to that of melt profile 202.

Melt profile 302 illustrates that the melting temperature of this growth melt decreases as the concentration of silicon decreases from 100% to about 55% at point 304. For example, when the growth melt is 100% silicon, the melting temperature of the growth melt is the familiar 1414 degrees centigrade for silicon. When the growth melt is 100% magnesium, the melting temperature of the growth melt is about 638 degrees centigrade for magnesium. In a particular example, crystal pulling to form a silicon crystal may begin with a growth melt starting with 80% silicon, 20% magnesium. The melting temperature of the growth melt decreases as more silicon is pulled from the growth melt to form the silicon crystal. When the concentration of silicon lowers to about 55%, the melting temperature of the growth melt suddenly begins to rise with decreasing silicon concentration. Accordingly, the temperature of the growth melt during a pulling process for silicon should follow melt profile 302, decreasing for some parts of the process and increasing for other parts of the process, depending of the silicon concentration. Thus, in this example, and using MOE system 100, temperature controller 134 may decrease the temperature of the growth melt as the concentration of the silicon decreases until the concentration lowers to about 55%. This is in contrast to crystal pulling from a growth melt that is a 100% silicon growth melt. In this case, the temperature of the growth melt is held constant at 1414 degrees centigrade, as indicated by line 306, because the melt temperature of a pure silicon growth melt does not change, even as silicon is pulled out to form a silicon crystal.

FIG. 4 is a flow diagram of a process 400 for crystal pulling from a growth melt that is produced by MOE, according to some embodiments. The process may be performed by an operator, which may be a person or persons, a computer processor (e.g., 126) executing computer-readable code, or a combination thereof. The process may be performed by the operator using MOE system 100, for example.

In this embodiment, via an electrical current used for electrolysis in a first vessel, the operator may use system 100 to heat an oxide material. Other methods of heating the oxide material include induction heating and microwave heating using a susceptor material, just to name a few examples. Claimed subject matter is not limited to any particular method of heating the oxide material. Heating the oxide material may allow for forming a liquid cathode in the melt but a liquid cathode may already be present while electrical current (reduction) adds additional material to the cathode. The oxide material may be a mixture of two or more metallic oxides. The liquid cathode, based on its density compared to the overall density of the oxide material, may generally collect at a bottom region of the first vessel so as to be in contact with a cathodic electrode of the electrolysis.

At 402, via electrolysis in the first vessel containing the melted oxide material, the operator may produce an iron- and oxygen-depleted electrolyte. At 404, the operator may control system 100 so that a second vessel of the system receives a portion of the iron- and oxygen-depleted electrolyte. At 406, the operator may crystal pull an element such as silicon from the iron- and oxygen-depleted electrolyte in the second vessel. The operator may use controller 126 to control positioning and motion of seed holder 122. For example, the controller may provide instructions to motion transducer 128 to move seed holder 122 to raise, lower, and rotate seed crystal 124 during the process of crystal pulling. These motions (of crystal pulling) occur while the temperature of the growth melt is simultaneously controlled and/or monitored. Such temperature control may be passive, active, or a combination of both methods. For example, passive temperature control may be a carefully, predetermined configuration of thermal insulation or cooling based on the thermal mass of the growth melt for which the system is designed. In addition to the thermal mass, process times, initial thermal conditions of various parts of the system, and the intrinsic properties of the growth melt may also be considered in the system design and/or control. Active temperature control may involve actively heating or cooling various parts of the system and/or the growth melt such as by using heating coils (active heating) or fluid circulation (active cooling), just to name a few examples. As discussed above, temperature control of the growth melt may be based on its melt profile.

Accordingly, at 408, the operator may, at least during the crystal pulling, control temperatures of the iron- and oxygen-depleted electrolyte in the second vessel based, at least in part, on the melt profile that represents the melt temperature of the iron- and oxygen-depleted electrolyte as a function of the concentration of the (formed crystal) element. In some implementations, the crystal pulling may result in a single crystal of one element that is pulled from a growth melt of that element mixed with one or more other elements. In some implementations, the crystal pulling may be performed in a vacuum. In some cases, the vacuum may be that of the lunar surface.

The foregoing description, for purposes of explanation, used specific nomenclature to provide a thorough understanding of the disclosure. However, it will be apparent to one skilled in the art that the specific details are not required in order to practice the systems and methods described herein. The foregoing descriptions of specific embodiments or examples are presented by way of examples for purposes of illustration and description. They are not intended to be exhaustive of or to limit this disclosure to the precise forms described. Many modifications and variations are possible in view of the above teachings. The embodiments or examples are shown and described in order to best explain the principles of this disclosure and practical applications, to thereby enable others skilled in the art to best utilize this disclosure and various embodiments or examples with various modifications as are suited to the particular use contemplated. It is intended that the scope of this disclosure be defined by the following claims and their equivalents.

We claim as follows:

1. A method for crystal pulling from a growth melt that is produced by molten oxide electrolysis, the method comprising:
via electrolysis in a first vessel containing a melted oxide material, producing an iron- and oxygen-depleted electrolyte;
receiving a portion of the iron- and oxygen-depleted electrolyte into a second vessel;
crystal pulling an element from the iron- and oxygen-depleted electrolyte in the second vessel; and
at least during the crystal pulling, controlling temperatures of the iron- and oxygen-depleted electrolyte in the second vessel based, at least in part, on a melt profile that represents a melt temperature of the iron- and oxygen-depleted electrolyte as a function of the concentration of the element.

2. The method of claim 1, wherein the element is silicon.

3. The method of claim 1, wherein the oxide material is a mixture of two or more metallic oxides.

4. The method of claim 1, wherein the second vessel is separated from the first vessel via a conduit that conveys the portion of the iron- and oxygen-depleted electrolyte from the first vessel.

5. The method of claim 4, wherein controlling temperatures of the iron- and oxygen-depleted electrolyte in the second vessel comprises at least partially controlling heat transfer of a flow of the portion of the iron- and oxygen-depleted electrolyte in the conduit.

6. The method of claim 1, wherein crystal pulling the element in the second vessel is performed while simultaneously performing the electrolysis in a first vessel.

7. The method of claim 1, wherein the electrolysis in the first vessel involves a liquid cathode that, based on density of the liquid cathode compared to density of the melted oxide material, collects at a bottom portion of the first vessel and is in contact with a cathodic electrode of the electrolysis.

8. The method of claim 1, further comprising collecting oxygen gas from the first vessel while simultaneously crystal pulling the element in the second vessel.

9. A method for purifying an iron- and oxygen-depleted melt, the method comprising:
crystal pulling an element from the iron- and oxygen-depleted melt; and
based, at least in part, on a melt profile that represents a melt temperature of the iron- and oxygen-depleted electrolyte as a function of the concentration of the element, changing the temperature of the iron- and oxygen-depleted melt as the concentration of the element decreases.

10. The method of claim 9 wherein the element is silicon.

11. The method of claim 9, wherein the iron- and oxygen-depleted melt is produced by electrolysis.

12. A molten oxide electrolysis (MOE) system comprising:
a first vessel that includes i) an anode and ii) a cathodic electrode in a bottom region of the first vessel, wherein
the cathodic electrode is configured to be in electrical communication with a melted oxide material in the first vessel,
the anode and the cathodic electrode are configured to provide an electrical current therebetween for a process of electrolysis of the melted oxide material, and
the process of electrolysis of the melted oxide material produces a liquid cathode in contact with the cathodic electrode;
a second vessel that is separated from the first vessel by a conduit for carrying, from the first vessel to the second vessel, a portion of the melted oxide material that is iron- and oxygen-depleted, wherein the portion of the melted oxide material that is iron- and oxygen-depleted is a growth melt;
a rod-mounted seed crystal of an element in or above the second vessel and configured to be immersed in the growth melt; and
temperature-control electronics configured to control the temperature of the growth melt based, at least in part, on a melt profile that represents a melt temperature of the growth melt as a function of the concentration of the element.

13. The MOE system of claim 12, wherein the element is silicon.

14. The MOE system of claim 13, wherein the temperature-control electronics are further configured to decrease the temperature of the portion of the growth melt as the concentration of the silicon decreases.

15. The MOE system of claim 13, wherein the temperature-control electronics are further configured to increase the temperature of the growth melt as the concentration of the silicon decreases.

16. The MOE system of claim 12, wherein the melted oxide material is a mixture of two or more metallic oxides.

17. The MOE system of claim 12, wherein the melted oxide material is derived from lunar regolith.

18. The MOE system of claim 12, further comprising an oxygen gas collecting port in the first vessel.

19. The MOE system of claim 12, wherein the rod-mounted seed crystal of the element is configured to produce a crystal of the element via a crystal pulling process.

20. The MOE system of claim 12, wherein the liquid cathode, based on density of the liquid cathode compared to density of the melted oxide material, collects in the bottom region of the first vessel.
